(19) United States
(12) Patent Application Publication
(10) Pub. No.: US 2025/0081863 A1
(43) Pub. Date: Mar. 6, 2025

(54) STRUCTURE TO REGULATE MULTI-FILAMENT FORMATION ON MEMORY STRUCTURE

(71) Applicant: International Business Machines Corporation, Armonk, NY (US)

(72) Inventors: Jin Ping Han, Yorktown Heights, NY (US); Ching-Tzu Chen, Ossining, NY (US); Kevin W. Brew, Niskayuna, NY (US); Timothy Mathew Philip, Albany, NY (US); Shawn Pinkett, Newburgh, NY (US)

(21) Appl. No.: 18/238,736

(22) Filed: Aug. 28, 2023

(51) Int. Cl. H10N 70/00; H10B 63/00; H10N 70/20

(52) U.S. Cl. CPC H10N 70/828; H10B 63/00; H10N 70/011; H10N 70/24; H10N 70/841

(57) ABSTRACT

A resistive random access memory device comprises: a bottom electrode; a bottom layer of dielectric material formed on the bottom electrode; a plurality of conductive contacts extending from the bottom electrode through the bottom layer of dielectric material; a top layer of dielectric material formed on the bottom layer of dielectric material and on the conductive contacts; a top electrode on the top layer of dielectric material; and at least one filament extending from the plurality of conductive contacts through the top layer of dielectric material to the top electrode.

### BACKGROUND

The exemplary embodiments described herein relate generally to computer memory structures and, more specifically, to structures for resistive random access memories and methods of their manufacture.

Resistive random access memory (ReRAM or RRAM) is a type of non-volatile (NV) random access memory (RAM) that works by changing the resistance across a dielectric solid-state material. RRAM consists of an insulating layer sandwiched between two metal electrodes and relies on the formation of conductive filaments via dielectric breakdown in the insulating layer and modulation of the length of these filaments corresponding to low resistance states (LRS) and high resistance states (HRS), respectively, in the insulator between two electrodes. RRAM has a lower programming voltage and faster write/read speed compared to flash memory and is seen as potential replacement for such memory. It is also seen as an alternative to programmable metallization cells/conductive bridge random access memory (PMC/CBRAM) which work by changing resistance across an insulating electrolyte through growth of conductive metal filaments within the electrolyte sandwiched between two metal electrodes.

Among all the emerging memory technology candidates, RRAM has significant advantages such as easy fabrication, simple metal-insulator-metal (MIM) structure, excellent scalability, nanosecond speed, long data retention, and compatibility with the current CMOS technology, thus offering a competitive solution to future digital memory as well as analog memory for in memory compute operation for AI technology.

However, conventional RRAM forming voltage generally requires at least 3.5 volts, which is considered to be a high power consumption compared to other memory types. Program noise and variability are also high due to stochastic filament formation dependent on systemic local defects in the device processes and structure, and due to stochastic modulation of the filament length during write programming. Regulating filament formation and programming in the process level generally provides a potential solution to mitigate the noise and variability as well as reducing the forming voltage. The structure and methods for regulating filament formation and programming also pertain to other filamentary memories beyond RRAM such as PMC and CBRAM.

### BRIEF SUMMARY

In one exemplary aspect, a resistive random access memory device comprises: a bottom electrode; a bottom layer of dielectric material formed on the bottom electrode; a plurality of conductive contacts extending from the bottom electrode through the bottom layer of dielectric material; a top layer of dielectric material formed on the bottom layer of dielectric material and on the conductive contacts; a top electrode on the top layer of dielectric material; and at least one filament extending from the plurality of conductive contacts through the top layer of dielectric material to the top electrode.

In another exemplary aspect, a method comprises: depositing a first dielectric material onto a bottom electrode; depositing a hard-mask onto the first dielectric material; etching the hard-mask and the first dielectric material into pillars down to the bottom electrode; depositing a conductive film onto exposed surfaces of the etched hard-mask layer and the first dielectric material; etching the conductive film from the bottom electrode; depositing a second dielectric material over the conductive film; planarizing down to the first dielectric material; depositing a third dielectric material over the upper surfaces of the first dielectric material and the second dielectric material and exposed surfaces of the conductive film to form a resistive random access memory layer; forming a top electrode on the resistive random access memory layer; and forming filaments in the resistive random access memory layer.

In another exemplary aspect, a method comprises: depositing a first dielectric material onto a bottom electrode; depositing a hard-mask onto the first dielectric material; etching the hard-mask and the first dielectric material down to the bottom electrode; depositing a conductive film onto exposed surfaces of the etched hard-mask and first dielectric material; depositing a soft dummy material over the conductive film and the first dielectric material; planarizing down to an upper level of the first dielectric material to configure the conductive film as a plurality of contacts; wet etching to remove the soft dummy material; depositing a second dielectric material over the first dielectric material and exposed surfaces of the conductive film; planarizing down to the second dielectric material to form a resistive random access memory layer; forming a top electrode on the resistive random access memory layer; and forming filaments in the resistive random access memory layer.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1 is a cross sectional view of one example embodiment of an RRAM structure incorporating pre-defined thin vertical conductive contacts;

FIG. 2 is a cross sectional view of a bottom electrode on which a first dielectric material is deposited in a step of fabricating the structure of FIG. 1;

FIG. 3 is a cross sectional view of the bottom electrode and the first dielectric material of FIG. 2 on which a hard-mask is deposited;

FIG. 4 is a cross sectional view of the layers of FIG. 3 after etching;

FIGS. 5A and 5B are cross sectional views of the etched structure of FIG. 4 on which an area-selective conductive material is deposited as a film;

FIG. 5B is a cross sectional view of the etched structure of FIG. on which a conductive material is deposited conformally and etched anisotropically to remove the top and bottom, leaving only the conductive sidewalls;

FIG. 6 is a cross sectional view of the layers of FIG. 5A on which a second dielectric material is deposited;

FIG. 7 is a cross sectional view of the layers of FIG. 6 after a chemical mechanical polish is carried out;

FIG. 8 is a cross sectional view of a deposition of the third dielectric material on the layers of FIG. 7;

FIG. 9 is a process flow diagram illustrating an exemplary method of fabricating the structure of FIG. 1;

FIG. 10 is a cross sectional view of another example embodiment of an RRAM structure incorporating pre-defined thin vertical conductive contacts;

FIG. 11 is a cross sectional view of a deposition of a second dielectric material on a first dielectric material in a step of fabricating the structure of FIG. 10;

FIG. 12 is a cross sectional view of the deposited second dielectric material indicating a thickness of material above contacts;

FIG. 13 is a cross sectional view of an alternate step in fabricating the structure of FIG. 1;

FIG. 14 is a cross sectional view of the layers of the structure of FIG. 13 after a chemical mechanical polish is carried out;

FIG. 15 is a cross sectional view of the layers of FIG. 14 after the hard-mask is removed;

FIG. 16 is a cross sectional view of the layers of FIG. 15 after a deposition of dielectric material; and

FIG. 17 is a process flow diagram illustrating another exemplary method of fabricating a RRAM structure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

The exemplary embodiments described herein pertain to RRAM device structures with pre-defined thin vertical conductive contacts embedded in parts of dielectric film layers sandwiched between two electrodes. The structures may include single or multiple pre-defined thin vertical conductive contacts. Through the use of such structures, forming voltages can be significantly lowered and conductive filaments can be formed at pre-defined locations. Hence power consumption and stochastic noise can be reduced.

Examples of RRAM structures disclosed herein have layers of dielectric material(s) with single or multiple units of pre-defined thin vertical conductive contacts embedded into part of at least one of the layers. The pre-defined vertical conductive contacts can be formed by sidewall spacer and/or selective area deposition to form thin films at sidewalls of semiconductor structures (bottomless spacer shape). The thickness of a top layer of dielectric, which is free of an embedded contact, can be adjusted by deposition to an optimal level for forming voltage reduction without reaching irreversible breakdown. The dielectric materials of the RRAM can be flexible, either the same or different, depending on the process method availability and reliability, with RRAM dielectric layers being sandwiched between the top electrode and the embedded vertical conductive contacts. Embodiments include integration with additions of conventional wet/RIE/deposition/thermal process, adhesion layers, and the like.

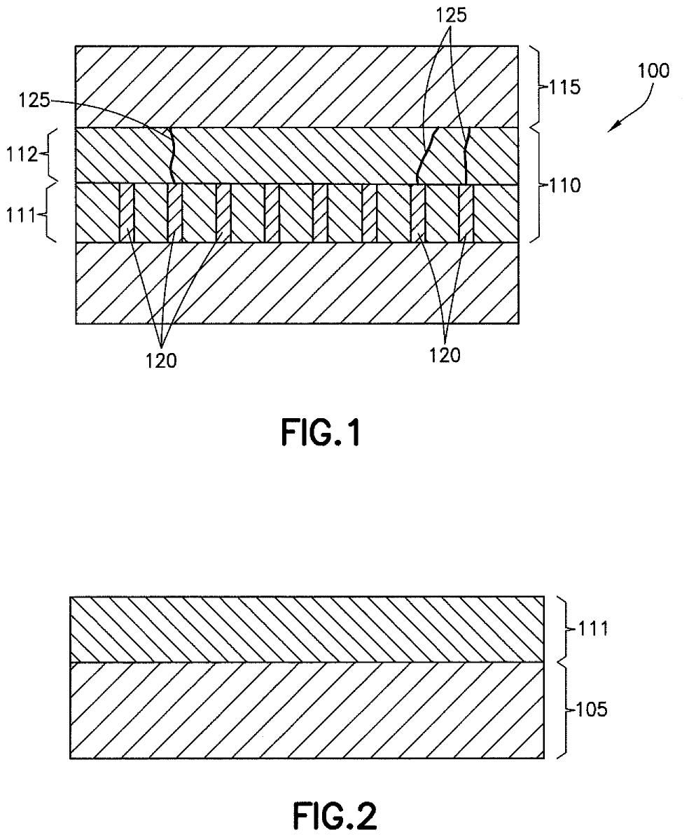

In FIG. 1, one example of an RRAM structure incorporating pre-defined thin vertical conductive contacts is shown generally at 100 and is hereinafter referred to as “structure 100.” Structure 100 comprises a bottom electrode 105 on which a device layer 110 is located, and a top electrode 115 on the device layer 110. The device layer 110 comprises a defined contact layer 111 and an RRAM layer 112. Conductive elements are formed in the defined contact layer 111. In one example, the conductive elements may be embedded conductive contacts comprising one or more conductive materials for controlled filament formation, such as metal, metal alloy, metal nitride, conductive metal oxide, 2-dimensional conductor, degenerately doped semiconductors, or topological semimetal, hereinafter referred to as “contacts 120,” disposed on bottom electrode 105 and extending through the defined contact layer 111. The contacts 120 can comprise one or more conductive materials (e.g. one or more of, Al, Cu, Pt, Pd, Ag, Au, Ru, W, WN, TiN, TaNₓ, AlNₓ or HfSi) based on metals, metal alloys, and metal nitride materials, or conductive oxide materials (e.g., one or more of WOₓ, AlOₓ, HfOₓ, TaOₓ, ZnO, TiOₓ, SrTiOₓ, or ZrO), or doped semiconductors (e.g., one or more of doped Si, SiGe, SiC, or Ge), or topological semimetals (e.g., one or more of TaAs, NbAs, AlPt, AlPd, GaPt, GaPd, CoSi, RhSi, CoGe, RhGe, NbGe₂, Co₂TiGe, MoTe₂, WTe₂, LaAlGe, or PrAlGe). The filaments 125 are electrically formed after the application of a voltage and extend through the material of the RRAM layer 112 to connect the contacts 120 with the top electrode 115. A process of fabricating the structure 100 is shown in FIGS. 2-9.

As shown in FIG. 2, the material of the defined contact layer 111 is deposited on the bottom electrode 105. The defined contact layer 111 comprises a first dielectric material such as silicon dioxide, silicon nitride, aluminum oxide, aluminum nitride, hafnium oxide, diamond-like carbon, chalcogenide glasses, or the like.

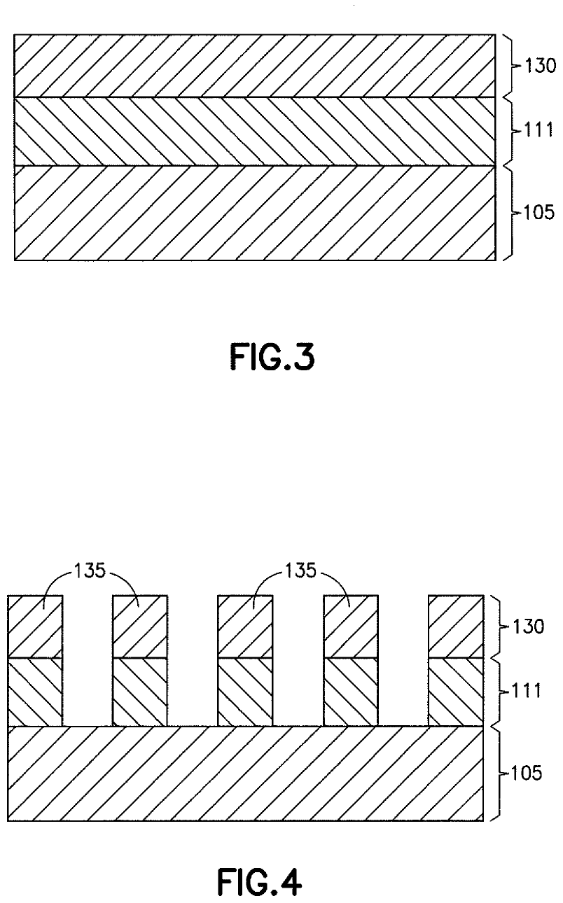

Referring to FIG. 3, a hard-mask layer 130 is deposited onto the defined contact layer 111. Materials from which the hard-mask layer 130 may be fabricated include, but are not limited to, polysilicon, TiN, SiN, organic planarization layers (OPLs). Deposition may be by chemical vapor deposition (CVD), physical vapor deposition (PVD), plasma enhanced chemical vapor deposition (PECVD), or similar methods.

Referring to FIG. 4, the hard-mask layer 130 and the defined contact layer 111 are etched down to the bottom electrode 105 to form pillars 135 of portions of the defined contact layer 111 topped with portions of the hard-mask layer 130 extending from the bottom electrode 105.

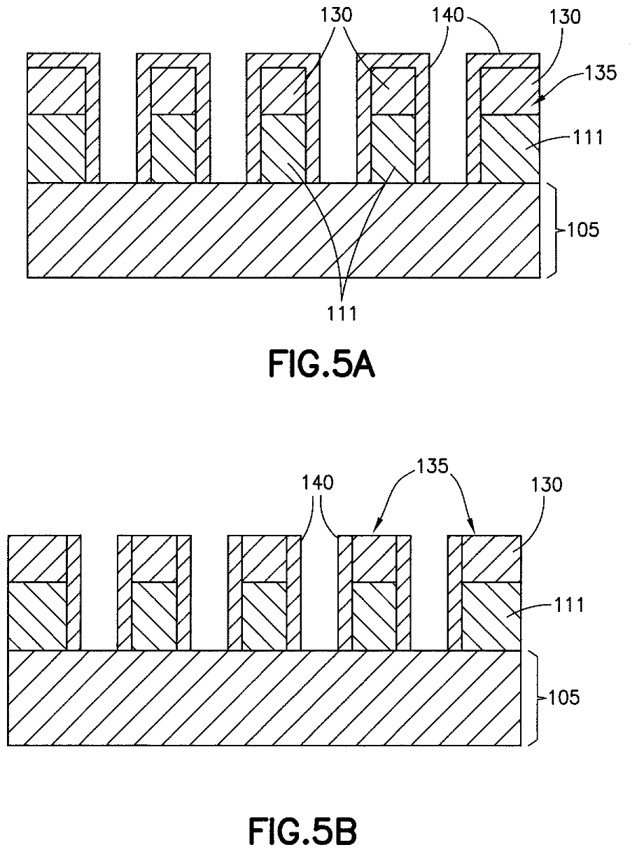

Referring to FIG. 5A, in one example, the conductive material may be deposited via area-selective deposition as a film 140 on upper surfaces and sides of the pillars 135, portions of the film 140 being used to form the contacts 120 in the defined contact layer 111. The film 140 may be deposited using a bottomless deposition technique.

Referring to FIG. 5B, in another example, the conductive material may be deposited conformally over the pillars 135 and etched anisotropically to remove the top and bottom, leaving only the conductive sidewalls 140.

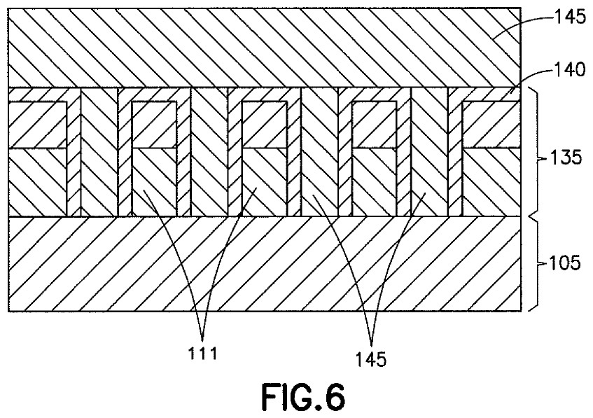

Referring to FIG. 6, a deposition of a second dielectric material may be carried out over the pillars 135 as shown in FIG. 5A to deposit a dielectric layer 145 over the film 140. The second dielectric material may be the same as the first dielectric material or it may be different.

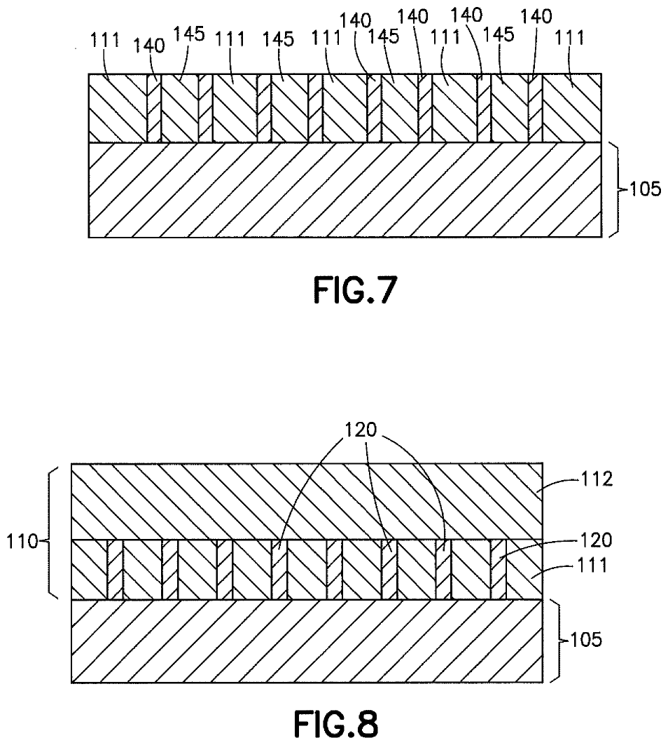

Referring to FIG. 7, a chemical mechanical polish (CMP) is carried out to planarize the dielectric layer 145 and the film 140 down to the defined contact layer 111. The vertical portions of the film 140 form the contacts 120.

Referring now to FIG. 8, a deposition of dielectric material is carried out to fill the RRAM layer 112 over the contacts 120 formed by the remaining portions of the film 140. The dielectric material of the RRAM layer 112 may be the same as or different from the first dielectric material in defined contact layer 111 and the second dielectric material in the dielectric layer 145. The top electrode 115 is deposited. After deposition of the top electrode 115, the filaments 125 are formed in the RRAM layer 112 to extend substantially vertically from upper ends of the contacts 120, as shown in FIG. 1. The filaments 125 may be formed by applying a voltage between the top electrode 115 and the bottom electrode 105 in a programming step to cause dielectric breakdown (e.g., an oxide vacancy filament formation mechanism) or they may be formed by electrostatic induced breakdown from charge concentration that may occur during disposition of 112 or the top electrode 115.

In the formed structure 100, the contacts 120 may be about 1.5 nanometers (nm) to about 50 nm in width, with a typical width being 10 nm. An aspect ratio (H/W) of the contacts 120 is about 2 to about 6, for example, when the material is ruthenium. Spacing between the contacts 120 may follow the aspect ratio of the spacing between the contacts and the thickness of the RRAM layer 112 (for example, spacing/thickness may be about 2 to about 10). A thickness of the RRAM dielectric materials between the tops of the contacts 120 and the top electrode may be about 5 nm to about 20 nm.

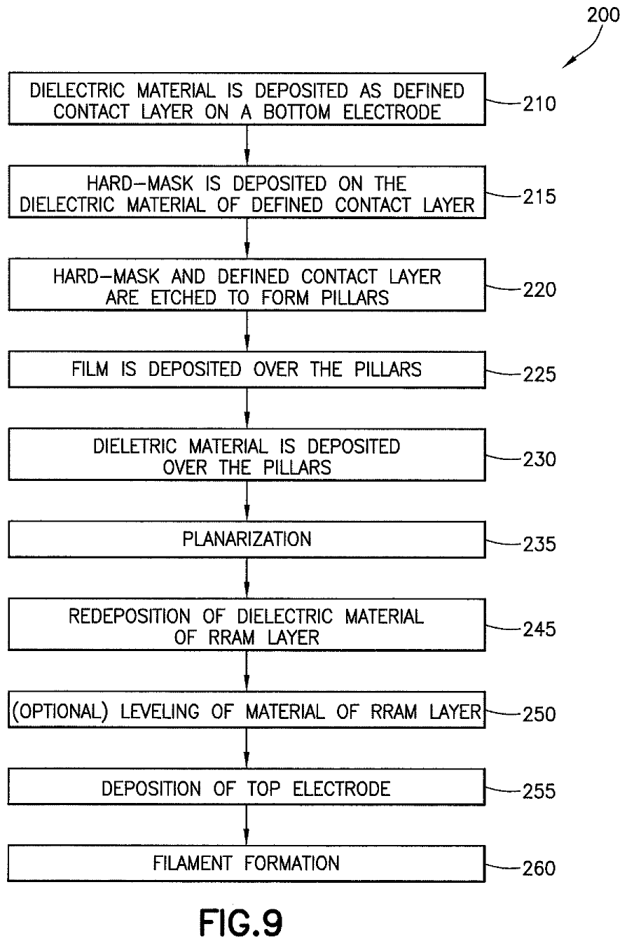

Referring now to FIG. 9, one example of a process flow for forming the structure 100 is shown at 200 and is hereinafter referred to as “process 200.” In the process 200, dielectric material is deposited as the defined contact layer onto the bottom electrode, as indicated at block 210. The hard-mask layer is deposited on the defined contact layer, as indicated at block 215. The materials of the hard-mask layer and the defined contact layer are etched to form pillars, as indicated at block 220, and the conductive film is deposited over the pillars, as indicated at block 225. As indicated at block 230, the dielectric material is deposited over and between the pillars. As indicated at block 235, planarization is carried out. Deposition of a dielectric material to form the RRAM layer is then carried out, as indicated at block 245. As indicated in block 250, an optional step of levelling the upper surface of the RRAM layer may be carried out, for example, by another planarization or by controlled deposition of the material of the RRAM layer. The top electrode is deposited, as indicated at block 255. As indicated at block 260, the filaments are formed.

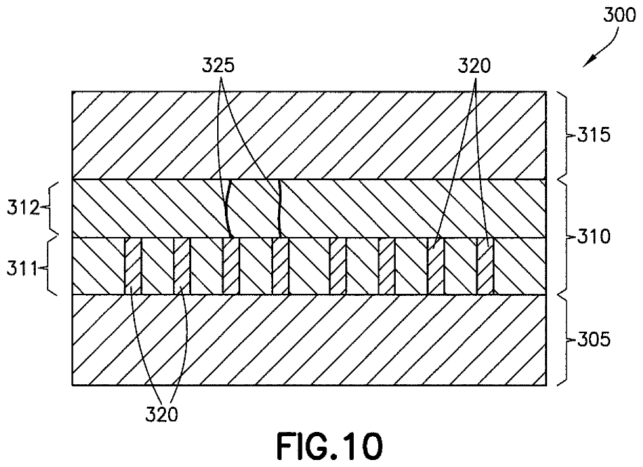

In FIG. 10, another example of an RRAM structure incorporating pre-defined thin conductive contacts is shown generally at 300 and is hereinafter referred to as “structure 300.” In structure 300, dielectric material is used to form a defined contact layer 311 and an RRAM layer 312 as a device layer 310 positioned between a bottom electrode 305 and a top electrode 315. Conductive elements in the forms of embedded memory conductive contacts for controlled filament formation, hereinafter referred to as “contacts 320,” which are formed from one or more conductive materials such as metal, metal alloy, metal nitride, conductive metal oxide, 2-dimensional conductor, doped semiconductor, or topological semimetal, as well as composites of such material, deposited as a film 340, extend from the bottom electrode 305. Filaments 325 connect the contacts 320 to the top electrode 315.

An example of a process of fabricating the RRAM structure 300 is the same as in FIGS. 2-4, but whereas a conductive material is disposed partially or disposed and partially removed in FIGS. 5A and 5B, a conformal conductive material deposition is carried out, and in fabricating the RRAM structure of FIG. 10 a conductive or semiconductive fill (e.g., Ru, TiN, TaN, or other composite structure comprising conductive and non-conductive materials) is deposited over the pillars, and planarized (CMP) down to an upper level of the defined contact layer 311.

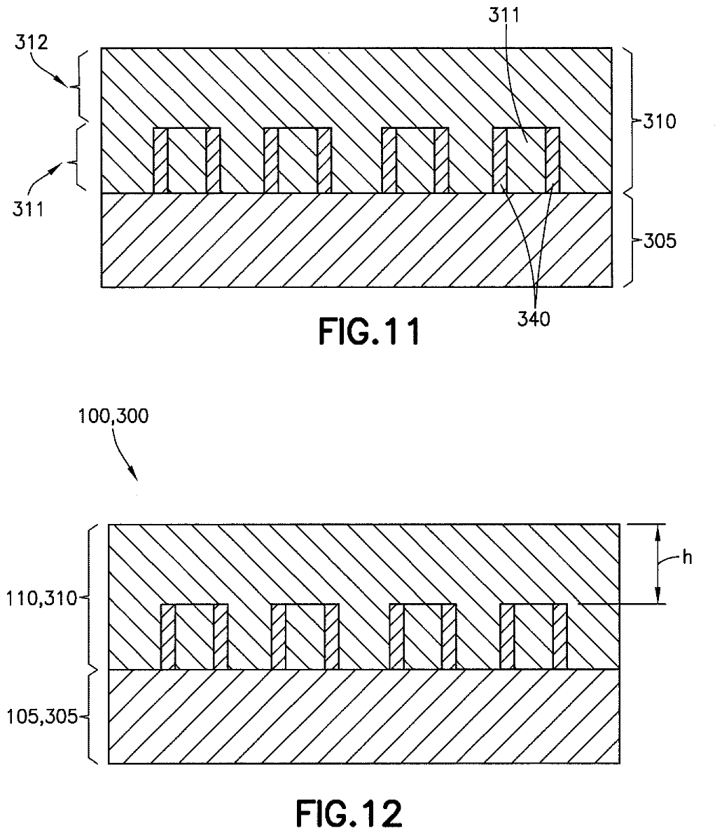

Referring now to FIG. 11, after planarization of the structure, a deposition of additional dielectric material of the RRAM layer 312 is carried out to fill the RRAM layer 312 over the tops of the remaining portions of the film 340 (forming the conductive contacts 320 on the dielectric material 311). A top electrode 315 (shown in FIG. 10) is deposited, and the filaments 325 (shown in FIG. 10) are formed by application of a voltage to extend from the vertical conductive contacts 320 through the dielectric material of the RRAM layer 312. As stated above, the filaments 125 can also be pre-formed by electrostatic induced breakdown from charge concentration in the conductive contacts.

Referring now to FIG. 12 and with regard to both the structure 100 of FIG. 1 and the structure 300 of FIG. 10, a thickness h of the dielectric materials for the RRAM layers 110, 310 may be controlled by the deposition of the dielectric materials in the upper portions of the RRAM layers 110, 310.

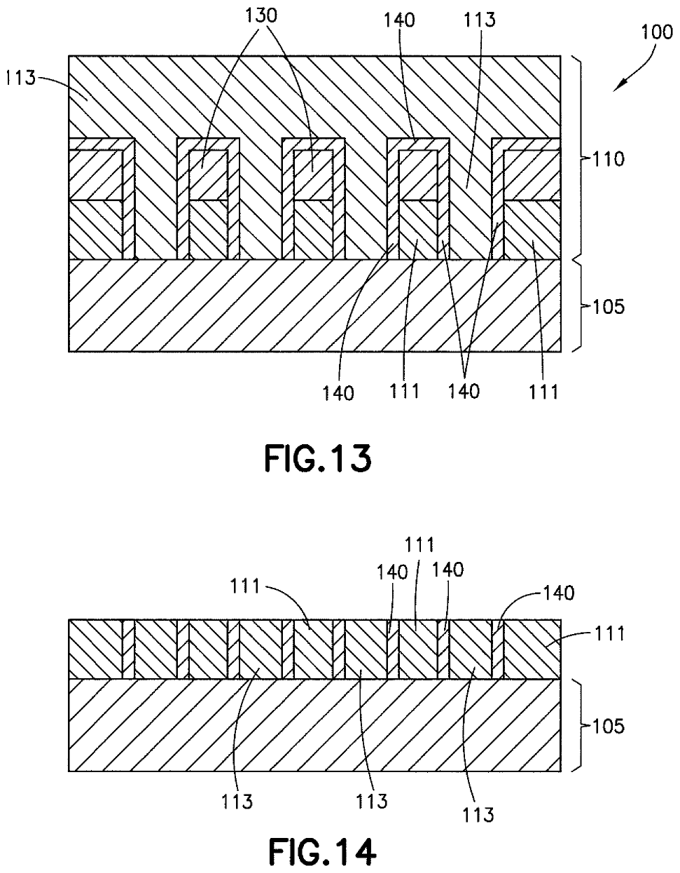

Another example process of fabricating the structure 100 is shown in FIGS. 13-16. This example process is similar to that shown above in which the area-selective metal or oxygen-vacancy-rich material is deposited as a film 140 on upper surfaces and sides of the structures and a soft dummy fill material 113 (for example, amorphous carbon (a-C)) is deposited on the structures. As shown in FIG. 13, the lower portion of device layer 110 is formed with the layer of dielectric material 111 on the lower electrode 105, the hard-mask layer 130 is deposited, etching is carried out, the film 140 is deposited, and the soft dummy fill material 113 is deposited.

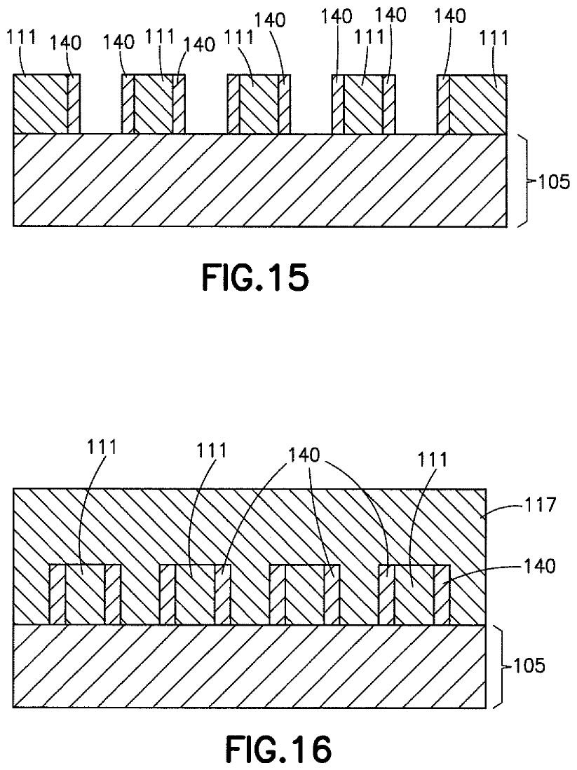

In FIG. 14, a CMP is then carried out down to the level of the dielectric material 111 between portions of the film 140 to form the contacts 120. The soft dummy fill material 113 is then etched away in a wet etching process, as shown in FIG. 15. Processing is then continued with a deposition of a different dielectric material 117 to fill the RRAM layer over the tops of the contacts 120, as shown in FIG. 16. An optional planarization may be carried out to level a top surface of the dielectric material 117. The top electrode 115 is then deposited. The filaments 125 are then formed by electrical programming and to extend through the dielectric materials to form the structure 100 with the filaments 125 connecting the contacts 120 to the top electrode 115.

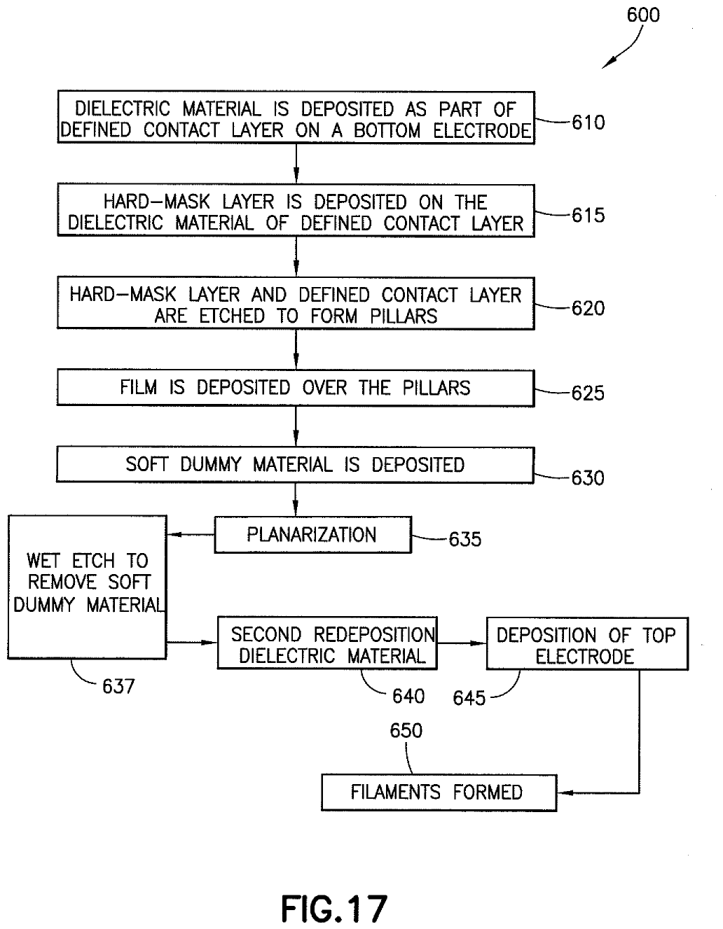

Referring now to FIG. 17, one example of a process flow for forming a structure with the soft dummy fill is shown at 600 and is hereinafter referred to as “process 600.” In the process 600, the dielectric material is deposited as the defined contact layer onto the bottom electrode, as indicated at block 610. The hard-mask layer is deposited on the defined contact layer, as indicated at block 615. The dummy dielectric layer and the defined contact layer are etched to form pillars, as indicated at block 620, and the film is deposited over the pillars, as indicated at block 625. As indicated at block 630, the soft dummy material is deposited over and between the pillars. As indicated at block 635, a planarization is carried out down to the upper level of the defined contact layer. At block 637, wet etching is carried out to remove the soft dummy material. At block 640 another deposition of dielectric material is then carried out with control of the thickness of the deposited dielectric material. The deposited dielectric material may be the same as the dielectric material deposited at block 610, or the deposited dielectric material may be different. As indicated at block 645, the top electrode is formed, and as indicated at block 650, the filaments are formed.

Benefits associated with the exemplary structures and processes disclosed herein include the reduction of forming voltages and currents, as well as reductions in the stochastic noise by regulating the filament with deposition processes and mitigation through the RRAM thickness modulation above the regulated filaments. A potential flexibility of using thin oxide FET instead of thick oxide FET may also be realized, which may reduce programming voltages and power consumption. The exemplary structures and processes disclosed herein may find use in strategic areas with regard to hardware and especially in artificial intelligence (AI) applications.

In one aspect, a resistive random access memory device comprises: a bottom electrode; a bottom layer of dielectric material formed on the bottom electrode; a plurality of conductive contacts extending from the bottom electrode through the bottom layer of dielectric material; a top layer of dielectric material formed on the bottom layer of dielectric material and on the conductive contacts; a top electrode on the top layer of dielectric material; and at least one filament extending from the plurality of conductive contacts through the top layer of dielectric material to the top electrode.

The bottom layer of dielectric material and the top layer of dielectric material may comprise a first dielectric material. The bottom layer of dielectric material may comprise a first dielectric material and the top layer of dielectric material may comprise a second dielectric material different from the first dielectric material. The bottom layer of dielectric material may comprise a first dielectric material and the top layer of dielectric material may comprise one or more dielectric materials being different from the first dielectric material. The at least one filament may comprise a conductive oxygen-vacancy-rich channel formed in the dielectric material between the top electrode and the plurality of conductive contacts. The top layer from which the oxygen-vacancy-rich channel is formed may comprise a metal oxide. The metal oxide may comprise one or more of WO, WOₓ, AlOₓ, AlNOₓ, HfOₓ, TaOₓ, ZnOₓ, ZrOₓ, TiOₓ, SrTiOₓ, MoOₓ, NbOₓ, CeOₓ, or combinations of the foregoing. A material of the conductive contacts may comprise one or more of Al, Cu, Pt, Pd, Ag, Au, Ru, W, WN, TiN, TaN, AlN, HfSi, or combinations of the foregoing.

In another aspect, a method comprises: depositing a first dielectric material onto a bottom electrode; depositing a hard-mask onto the first dielectric material; etching the hard-mask and the first dielectric material into pillars down to the bottom electrode; depositing a conductive film onto exposed surfaces of the etched hard-mask layer and the first dielectric material; etching the conductive film from the bottom electrode; depositing a second dielectric material over the conductive film; planarizing down to the first dielectric material; depositing a third dielectric material over the upper surfaces of the first dielectric material and the second dielectric material and exposed surfaces of the conductive film to form a resistive random access memory layer; forming a top electrode on the resistive random access memory layer; and forming filaments in the resistive random access memory layer.

The first dielectric material, the second dielectric material, and the third dielectric material may be the same. The first dielectric material and the second dielectric material may be the same, and the third dielectric material may be different from the first dielectric material and the second dielectric material. The third dielectric material may be a composite formed from a plurality of oxygen-vacancy-rich materials. The method may further comprise adjusting a thickness of the deposited third dielectric material before forming the top electrode on the resistive random access memory layer. Planarizing down to the first dielectric material may configure the conductive film as a plurality of contacts extending vertically from the bottom electrode. Forming filaments in the resistive random access memory layer may comprise applying a voltage across the contacts and the top electrode.

In another aspect, a method comprises: depositing a first dielectric material onto a bottom electrode; depositing a hard-mask onto the first dielectric material; etching the hard-mask and the first dielectric material down to the bottom electrode; depositing a conductive film onto exposed surfaces of the etched hard-mask and first dielectric material; depositing a soft dummy material over the conductive film and the first dielectric material; planarizing down to an upper level of the first dielectric material to configure the conductive film as a plurality of contacts; wet etching to remove the soft dummy material; depositing a second dielectric material over the first dielectric material and exposed surfaces of the conductive film; planarizing down to the second dielectric material to form a resistive random access memory layer; forming a top electrode on the resistive random access memory layer; and forming filaments in the resistive random access memory layer.

The first dielectric material and the second dielectric material may be the same. The second dielectric material may be a composite formed from a plurality of oxygen-vacancy-rich materials. Forming filaments in the resistive random access memory layer may comprise applying a voltage across the plurality of contacts and the top electrode.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A resistive random access memory device, comprising:
a bottom electrode;
a bottom layer of dielectric material formed on the bottom electrode;
a plurality of conductive contacts extending from the bottom electrode through the bottom layer of dielectric material;
a top layer of dielectric material formed on the bottom layer of dielectric material and on the conductive contacts;
a top electrode on the top layer of dielectric material; and
at least one filament extending from the plurality of conductive contacts through the top layer of dielectric material to the top electrode.

2. The resistive random access memory device of claim 1, wherein the bottom layer of dielectric material and the top layer of dielectric material comprise a first dielectric material.

3. The resistive random access memory device of claim 1, wherein the bottom layer of dielectric material comprises a first dielectric material and the top layer of dielectric material comprises a second dielectric material different from the first dielectric material.

4. The resistive random access memory device of claim 1, wherein the bottom layer of dielectric material comprises a first dielectric material and the top layer of dielectric material comprises one or more dielectric materials being different from the first dielectric material.

5. The resistive random access memory device of claim 1, wherein the at least one filament comprises a conductive oxygen-vacancy-rich channel formed in the dielectric material between the top electrode and the plurality of conductive contacts.

6. The resistive random access memory device of claim 5, wherein the top layer from which the oxygen-vacancy-rich channel is formed comprises a metal oxide.

7. The resistive random access memory device of claim 6, wherein the metal oxide comprises one or more of WO, WOₓ, AlOₓ, AlNOₓ, HfOₓ, TaOₓ, ZnOₓ, ZrOₓ, TiOₓ, SrTiOₓ, MoOₓ, NbOₓ, CeOₓ, or combinations of the foregoing.

8. The resistive random access memory device of claim 1, wherein a material of the conductive contacts comprises one or more of Al, Cu, Pt, Pd, Ag, Au, Ru, W, WN, TiN, TaN, AlN, HfSi, or combinations of the foregoing.

9. A method, comprising:
depositing a first dielectric material onto a bottom electrode;
depositing a hard-mask onto the first dielectric material;
etching the hard-mask and the first dielectric material into pillars down to the bottom electrode;
depositing a conductive film onto exposed surfaces of the etched hard-mask layer and the first dielectric material;
etching the conductive film from the bottom electrode;
depositing a second dielectric material over the conductive film;
planarizing down to the first dielectric material;
depositing a third dielectric material over the upper surfaces of the first dielectric material and the second dielectric material and exposed surfaces of the conductive film to form a resistive random access memory layer;
forming a top electrode on the resistive random access memory layer; and
forming filaments in the resistive random access memory layer.

10. The method of claim 9, wherein the first dielectric material, the second dielectric material, and the third dielectric material are the same.

11. The method of claim 9, wherein the first dielectric material and the second dielectric material are the same, and the third dielectric material is different from the first dielectric material and the second dielectric material.

12. The method of claim 9, wherein the third dielectric material is a composite formed from a plurality of oxygen-vacancy-rich materials.

13. The method of claim 9, further comprising adjusting a thickness of the deposited third dielectric material before forming the top electrode on the resistive random access memory layer.

14. The method of claim 9, wherein planarizing down to the first dielectric material configures the conductive film as a plurality of contacts extending vertically from the bottom electrode.

15. The method of claim 14, wherein forming filaments in the resistive random access memory layer comprises applying a voltage across the contacts and the top electrode.

16. A method, comprising:
depositing a first dielectric material onto a bottom electrode;
depositing a hard-mask onto the first dielectric material;
etching the hard-mask and the first dielectric material down to the bottom electrode;
depositing a conductive film onto exposed surfaces of the etched hard-mask and first dielectric material;
depositing a soft dummy material over the conductive film and the first dielectric material;
planarizing down to an upper level of the first dielectric material to configure the conductive film as a plurality of contacts;
wet etching to remove the soft dummy material;
depositing a second dielectric material over the first dielectric material and exposed surfaces of the conductive film;
planarizing down to the second dielectric material to form a resistive random access memory layer;
forming a top electrode on the resistive random access memory layer; and
forming filaments in the resistive random access memory layer.

17. The method of claim 16, wherein the first dielectric material and the second dielectric material are the same.

18. The method of claim 16, wherein the second dielectric material is a composite formed from a plurality of oxygen-vacancy-rich materials.

19. The method of claim 16, wherein forming filaments in the resistive random access memory layer comprises applying a voltage across the plurality of contacts and the top electrode.
